(19) United States
(12) Patent Application Publication
(10) Pub. No.: US 2015/0244146 A1
(43) Pub. Date: Aug. 27, 2015

(54) SEMICONDUCTOR RING LASER APPARATUS

(71) Applicant: V TECHNOLOGY CO., LTD., Kanagawa (JP)

(72) Inventors: Koichi Kajiyama, Kanagawa (JP); Toshimichi Nasukawa, Kanagawa (JP); Shin Ishikawa, Kanagawa (JP); Masayasu Kanao, Kanagawa (JP)

(73) Assignee: V TECHNOLOGY CO., LTD., Kanagawa (JP)

(21) Appl. No.: 14/427,532

(22) PCT Filed: Sep. 4, 2013
(86) PCT No.: PCT/JP2013/073778

§ 371 Date: Mar. 11, 2015

(30) Foreign Application Priority Data
Sep. 14, 2012 (JP) 2012-203152

(51) Int. Cl. H01S 5/10; H01S 5/20; H01S 5/026; H01S 5/042; H01S 5/0683; H01S 5/02; H01S 5/30; H01S 3/083

(52) U.S. Cl. CPC H01S 5/1071; H01S 5/305; H01S 5/2031; H01S 3/083; H01S 5/0425; H01S 5/0683; H01S 5/021; H01S 5/0261; H01S 5/3054

(57) ABSTRACT

Provided is a semiconductor ring laser apparatus including an Si semiconductor substrate, a ring resonator configured by an optical waveguide formed in the Si semiconductor substrate, a semiconductor laser part that is provided with a light emitting amplification part at least in a part of the optical waveguide and that generates two beams of laser light traveling around in opposite directions in the ring resonator, and a light detection part formed in the Si semiconductor substrate to extract the two beams of laser light from the ring resonator and detect a frequency difference between the two beams of laser light. The light emitting amplification part includes a pn junction obtained by annealing on a second semiconductor layer, which is obtained by doping a first semiconductor layer in the Si semiconductor substrate with boron at high concentration, the annealing being performed while radiating light onto the second semiconductor layer.

### TECHNICAL FIELD

The present invention relates to a semiconductor ring laser apparatus with which a ring laser gyro can be configured.

### RELATED ART

As a ring laser apparatus, a gas ring laser apparatus using He—Ne gas or the like as a laser light emitting medium and a solid ring laser apparatus using a solid laser device as a laser light emitting medium are known. A gas ring laser apparatus has practical defects such as a large size of the apparatus, the necessity of vacuum technology, short life, and large power consumption due to high voltage being necessary for excitation. In contrast, a solid ring laser apparatus has advantages in that size reduction of the apparatus, longer life, reduction in power consumption, improvement in reliability, and the like can be expected. However, there is a technical problem that an optical system for focusing on a laser solid device with an excitation light source for excitation of the laser solid device within a ring resonator becomes necessary, thereby increasing the size of the apparatus.

As a proposal for solving such a problem, Patent Literature 1 below proposes a semiconductor ring laser apparatus in which a semiconductor laser device coated with an antireflection film on both end surfaces is arranged within an optical path of a ring resonator configured on a substrate, and a driving power source for the semiconductor laser device is provided to directly cause laser oscillation with the driving power source.

### RELATED ART LITERATURE

Patent Literature 1: Japanese Patent Application Laid-open No. 2006-319104

### SUMMARY OF THE INVENTION

With the conventional semiconductor ring laser apparatus described above, a lens optical system for focusing light from an excitation light source is unnecessary. However, there has been a problem that, due to the semiconductor laser device being arranged separately within the optical path of the ring resonator formed on the substrate, optical axis alignment for the optical path set on the substrate and output light of the semiconductor laser device becomes necessary, and stable oscillation of a ring laser cannot be obtained unless the optical axis alignment is performed precisely.

Upon arrangement of a reflector for forming the ring resonator or a light receiving device for angular velocity detection on the substrate, arrangement with high precision in the positional relationship thereof has been necessary. Therefore, there has been a problem that production is difficult, stable oscillation of the ring laser cannot be obtained also unless the arrangements are performed precisely in terms of positional precision, and angular velocity detection with high precision cannot be performed.

In the case where the conventional semiconductor ring laser apparatus is configured as a ring laser gyro, there has been a problem in that demand for achieving an extremely small size and extremely light weight for desired applications in various technical fields cannot be met, since an arithmetic process circuit that calculates the angular velocity from a detected value of the frequency difference between two beams of laser light traveling around in opposite directions in the ring resonator needs to be provided separately.

One example of a task of the present invention is to deal with such a problem. That is, an object of the present invention is to enable stable oscillation of a ring laser, enable angular velocity detection with high precision, allow demand for achieving an extremely small size and extremely light weight to be met, and the like.

In order to achieve such an object, a semiconductor ring laser apparatus of the present invention is provided with an Si semiconductor substrate, a ring resonator configured by an optical waveguide formed on the Si semiconductor substrate, a semiconductor laser part that is provided with a light emitting amplification part at least in a part of the optical waveguide and that generates two beams of laser light traveling around in opposite directions in the ring resonator, and a light detection part formed on the Si semiconductor substrate to extract the two beams of laser light from the ring resonator and detect a frequency difference between the two beams of laser light. The light emitting amplification part includes a pn junction obtained by performing an anneal treatment with light radiation to a second semiconductor layer which is obtained by doping a first semiconductor layer of the Si semiconductor substrate with B (boron) at high concentration.

In the present invention having such characteristics, the common first semiconductor layer of the Si semiconductor substrate is doped with B (boron) at high concentration to form the second semiconductor layer, and the semiconductor ring laser apparatus is formed on an Si semiconductor substrate by using a light emitting amplification function of the pn junction obtained by performing the anneal treatment on the second semiconductor layer while radiating light onto the second semiconductor layer. By so doing, the light emitting amplification part can be formed in a part of the optical waveguide. Therefore, a complex optical axis alignment becomes unnecessary, and stable oscillation of a ring laser becomes possible. Since the arithmetic processing part that performs an arithmetic process of a detection signal of the light detection part can be incorporated integrally in the Si semiconductor substrate, demand for achieving an extremely small size and extremely light weight can be met.

### BRIEF DESCRIPTION OF THE DRAWINGS

FIG. 1 is an illustration showing a semiconductor ring laser apparatus according to one embodiment of the present invention.

FIG. 2 is an illustration showing a semiconductor ring laser apparatus according to one embodiment of the present invention.

FIG. 3(a), FIG. 3(b), FIG. 3(c), and FIG. 3(d) are illustrations showing the structure of and a method of forming a light emitting amplification part and a light detection part in the semiconductor ring laser apparatus according to the embodiment of the present invention.

FIG. 4(a), FIG. 4(b), FIG. 4(c), FIG. 4(d), and FIG. 4(e) are illustrations showing the structure of and a method of forming an optical waveguide in the semiconductor ring laser apparatus according to the embodiment of the present invention.

FIG. 5(a) and FIG. 5(b) are illustrations showing one example of the structure of the light detection part in the semiconductor ring laser apparatus according to the embodiment of the present invention.

### DETAILED DESCRIPTION OF PREFERRED EMBODIMENTS

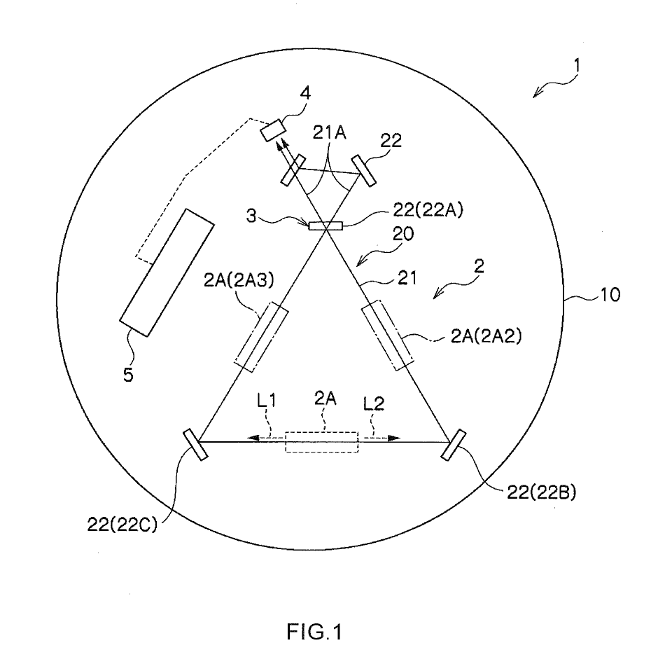

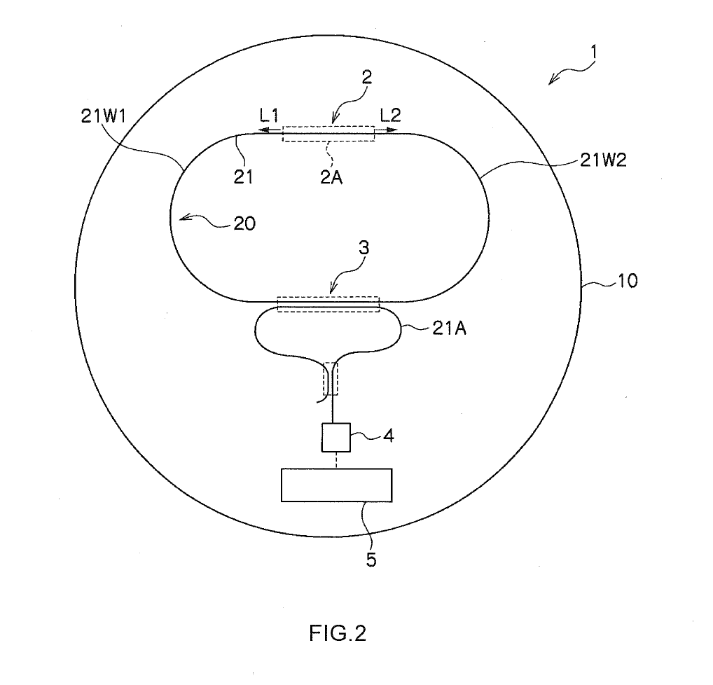

An embodiment of the present invention will be described below with reference to the drawings. FIG. 1 and FIG. 2 are illustrations showing a semiconductor ring laser apparatus according to one embodiment of the present invention. A semiconductor ring laser apparatus 1 is provided with an Si semiconductor substrate (Si wafer) 10. The Si semiconductor substrate 10 is formed with an optical waveguide 21, and a ring resonator 20 is configured by the optical waveguide 21. In an example shown in FIG. 1, the ring resonator 20 has a plurality of linear optical waveguides of which the direction changes at a plurality of reflection parts 22 (22A, 22B, and 22C) formed on the Si semiconductor substrate 10. In an example shown in FIG. 2, the ring resonator 20 has an annular optical waveguide including curved optical waveguides 21W1 and 21W2. The reflection part 22 herein forms an etching groove on the Si semiconductor substrate 10 and can be formed by filling a substance with a different refractive index therein, forming a metal surface on the side surface of the groove, or the like.

The semiconductor ring laser apparatus 1 is provided with a semiconductor laser part 2 on the Si semiconductor substrate 10. The semiconductor laser part 2 may be a ring laser configured by a light emitting amplification part 2A formed at least in a part of the optical waveguide 21 and the ring resonator 20, or may be configured as a resonator in which an etching groove is formed on both sides of the light emitting amplification part 2A and the side surface thereof is provided with a semi-transmissive reflecting surface. The semiconductor laser part 2 generates two beams of laser light (laser light L1 and laser light L2) that travel around in opposite directions in the ring resonator 20. As shown in FIG. 1, two (light emitting amplification parts 2A1 and 2A2), three (light emitting amplification parts 2A1, 2A2, and 2A3), or more of the light emitting amplification part 2A can be provided to the optical waveguide 21.

The semiconductor ring laser apparatus 1 is provided with a laser light extraction part 3 that extracts the two beams of laser light L1 and L2 from the ring resonator 20. The laser light extraction part 3 is configured by making a reflection part 22A provided between the optical waveguide 21 forming the ring resonator 20 and an extraction optical waveguide 21A into a half mirror (beam splitter) in the example shown in FIG. 1, and is configured by an optical directional coupler formed between the optical waveguide 21 forming the ring resonator 20 and the extraction optical waveguide 21A in the example shown in FIG. 2.

The semiconductor ring laser apparatus 1 is provided with a light detection part 4 that detects the frequency difference between the two beams of laser light L1 and L2 extracted from the laser light extraction part 3. The light detection part 4 is formed on the Si semiconductor substrate 10 and formed integrally at an end part of the extraction optical waveguide 21A. The light detection part 4 can detect the frequency difference between the laser light L1 and L2 by detecting the beat frequency of the laser light L1 and L2.

In the semiconductor ring laser apparatus 1, an arithmetic processing part 5 that performs an arithmetic process of a detection signal detected by the light detection part 4 is provided on the Si semiconductor substrate 10. The arithmetic processing part 5 may be formed with an arithmetic processing circuit by a semiconductor device incorporated in the Si semiconductor substrate 10 or may be configured by an IC chip mounted on the Si semiconductor substrate 10.

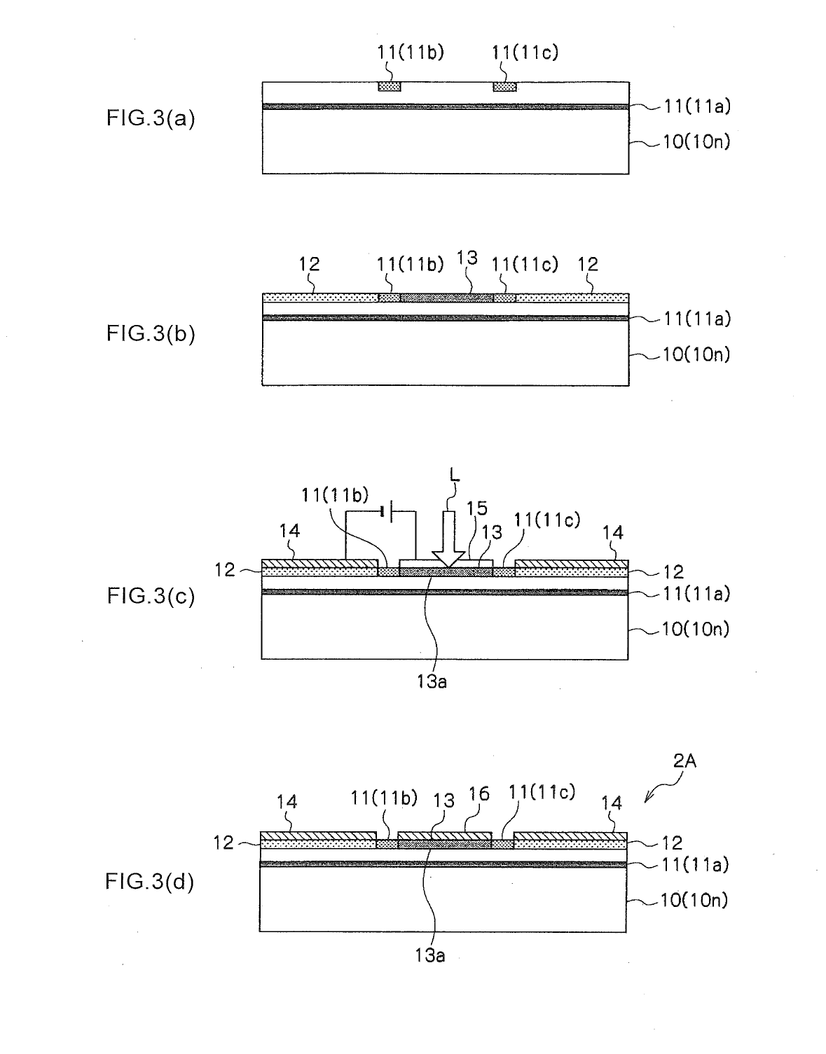

FIGS. 3(a), 3(b), 3(c), and 3(d) are illustrations showing one example of the structure of and a method of forming the light emitting amplification part in the semiconductor ring laser apparatus according to the embodiment of the present invention. First, a first semiconductor layer 10n doped with arsenic (As) is formed in the Si semiconductor substrate 10. Herein, the first semiconductor layer 10n is an n-type semiconductor layer.

Next, as shown in FIG. 3(a), a SiO₂ insulation layer 11 is formed through oxygen implantation or the like in the first semiconductor layer 10n. In the example in the drawing, an inner insulation layer 11a is formed inside the first semiconductor layer 10n, and a pair of surface insulation layers 11b and 11c are formed on the surface of the first semiconductor layer 10n. The inner insulation layer 11a can be formed by causing diffusion of an SiO₂ layer inside through a process of oxidation by heating after oxygen implantation on the surface of the Si semiconductor substrate 10, forming a Si film on the surface after forming the SiO₂ layer on the surface of the Si semiconductor substrate 10, or the like. The pair of surface insulation layers 11b and 11c can be formed by performing oxygen implantation in a mask opening formed in a pattern in a photolithography step and a process of heating by oxidation or the like.

Next, as shown in FIG. 3(b), an n+ layer 12 is formed by further doping the outside of the surface insulation layers 11b and 11c with arsenic (As), and a second semiconductor layer (p-type semiconductor layer) 13 is formed by doping with boron (B) between the surface insulation layers 11b and 11c at high concentration. As shown in FIG. 3(c), a metal electrode 14 is formed on the n+ layer 12, a transparent electrode (ITO or the like) 15 is formed on the second semiconductor layer 13, and then forward voltage is applied between the metal electrode 14 and the transparent electrode 15 to cause diffusion of boron (B) through an anneal treatment with Joule heat of current flowing in a pn junction 13a. By irradiating the pn junction 13a with light L in a process of the anneal treatment, a dressed photon is generated near the pn junction 13a.

The Si semiconductor substrate itself is an indirect transition semiconductor and is low in light emitting efficiency. Useful light emission cannot be obtained by merely forming a pn junction. That itself does not have optical transparency in a visual light range. In contrast, highly-efficient and high-output pn junction type light emitting is made possible by subjecting the Si semiconductor substrate to phonon-assisted annealing to generate a dressed photon near a pn junction and cause a change in Si that is an indirect transition semiconductor into an apparent direct transition semiconductor. One example of boron (B) doping conditions for obtaining such pn junction type light emitting is 5×10¹³/cm² in dose density and 700 keV in acceleration energy at the time of implantation. The wavelength of the light L radiated in an anneal process is in a desired wavelength band in a visual light range.

Then, as shown in FIG. 3(d), the light emitting amplification part 2A in which the pn junction 13a is an active layer is formed by removing the transparent electrode 15 and forming a metal electrode 16 on the second semiconductor layer 13. By applying voltage between the metal electrode 14 and the metal electrode 16, the light emitting amplification part 2A releases light of a wavelength equivalent to the wavelength of the light L radiated in the anneal process from the pn junction 13a.

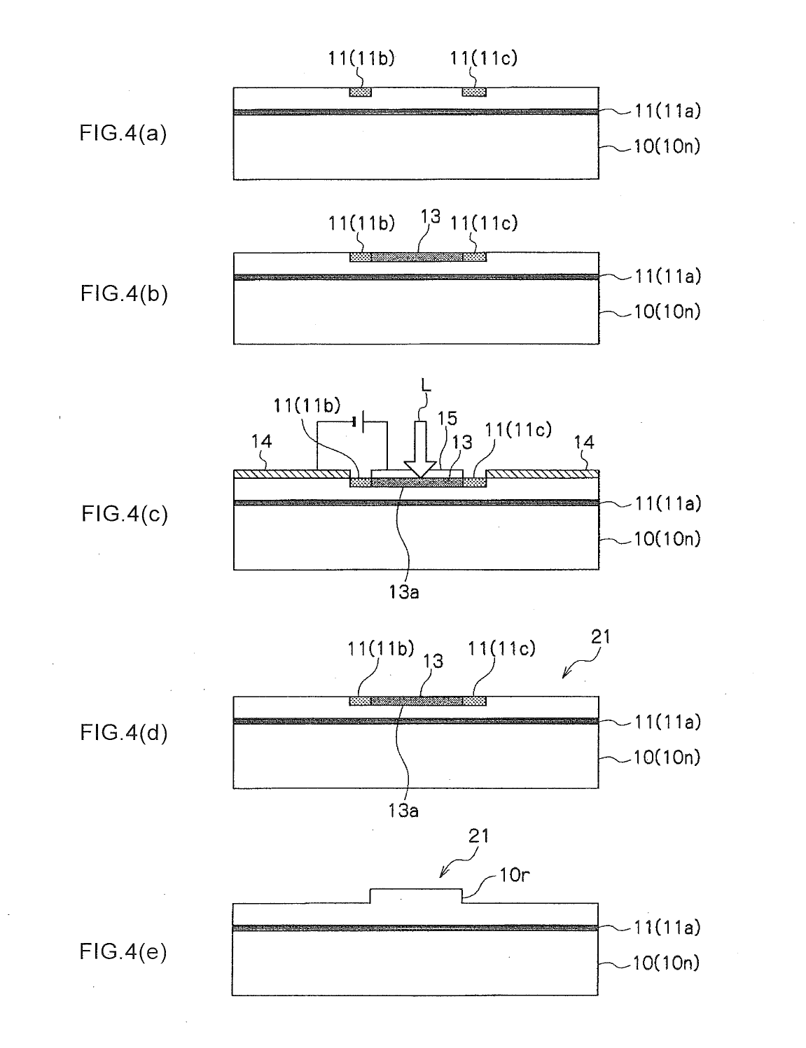

FIGS. 4(a), 4(b), 4(c), 4(d), and 4(e) are illustrations showing one example of the structure of and a method of forming the optical waveguide in the semiconductor ring laser apparatus according to the embodiment of the present invention. A step shown in FIG. 4(a) is performed in the same step as in FIG. 3(a) described above. The inner insulation layer 11a is formed inside the first semiconductor layer 10n, and the pair of surface insulation layers 11b and 11c are formed on the surface of the first semiconductor layer 10n. Next, a step shown in FIG. 4(b) is performed in the same step as a step shown in FIG. 3(b). Herein, the n+ layer 12 is omitted, and the second semiconductor layer 13 is formed between the pair of surface insulation layers 11b and 11c.

A step shown in FIG. 4(c) is performed in the same step as a step shown in FIG. 3(c). The metal electrode 14 is formed on the first semiconductor layer 10n outside the pair of surface insulation layers 11b and 11c, the transparent electrode (ITO or the like) 15 is formed on the second semiconductor layer 13, and then forward voltage is applied between the metal electrode 14 and the transparent electrode 15 to cause diffusion of boron (B) through an anneal treatment with Joule heat of current flowing in the pn junction 13a. By irradiating the pn junction 13a with light L in a process of the anneal treatment, a dressed photon is generated near the pn junction 13a.

Then, as shown in FIG. 4(d), the optical waveguide 21 in which the second semiconductor layer 13 is a light guide layer and the surface insulation layers 11b and 11c are a cladding layer is formed by removing the metal electrode 14 and the transparent electrode 15. The method of forming the optical waveguide 21 shown in FIG. 4(a) to FIG. 4(d) is not limiting. For example, as shown in FIG. 4(e), the optical waveguide 21 of a rib type can be formed by forming a rib 10r in the first semiconductor layer 10n formed with the inner insulation layer 11a. Light that propagates through the optical waveguide 21 in the example shown in FIG. 4(e) is limited to infrared light capable of transmitting through a Si layer.

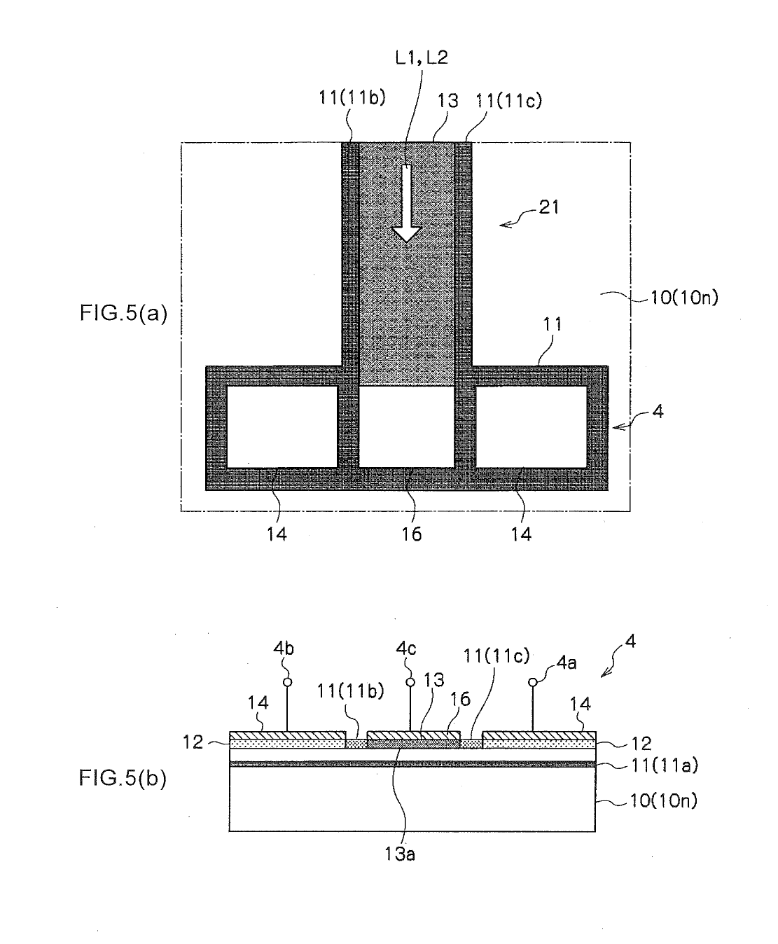

FIGS. 5(a) and 5(b) are illustrations showing one example of the structure of the light detection part in the semiconductor ring laser apparatus according to the embodiment of the present invention. As shown in FIG. 5(b), the light detection part 4 is provided with a structure having the pn junction 13a in a similar manner to the light emitting amplification part 2A and can be formed in the same steps as formation steps shown in FIGS. 3(a) to 3(d). The light detection part 4 is provided with a flat surface structure as shown in FIG. 5(a). The light detection part 4 is formed as an extension of the optical waveguide 21 in which the second semiconductor layer 13 is a light guide layer and the surface insulation layers 11b and 11c are a cladding layer. In the light detection part 4, a zero bias or reverse bias is applied between terminals 4a and 4b connected to the metal electrode 14 of the light detection part 4 and a terminal 4c connected to the metal electrode 16 to output a change in current generated by entrance of the laser light L1 and L2 propagating through the optical waveguide 21. The light detection part 4 is not limited to the example shown in FIG. 5 and can be formed of a light receiving device or the like mounted or connected on the Si semiconductor substrate 10.

The behavior of the semiconductor ring laser apparatus 1 of the present invention will be described with an example of a ring laser gyro. The ring laser gyro detects the angular velocity using the Sagnac effect. When the semiconductor ring laser apparatus 1 rotates, a difference occurs in frequency between the two beams of laser light L1 and L2 traveling around in opposite directions in the ring resonator 20. Therefore, by detecting the difference with the light detection part 4, the rotation behavior of the semiconductor ring laser apparatus 1 can be detected.

When current that is greater than or equal to a threshold value is injected to the light emitting amplification part 2A of the optical waveguide 21, the laser light L1 that propagates in the clockwise direction through the optical waveguide 21 forming the ring resonator 20 of the semiconductor laser part 2 and the laser light L2 that propagates in the counterclockwise direction are excited. A part of the laser light L1 and L2 propagates through the extraction optical waveguide 21A via the laser light extraction part 3 and enters the light detection part 4 formed at the end part of the extraction optical waveguide 21A. Since the laser light L1 and L2 extracted by the extraction optical waveguide 21A is synthesized and enters the light detection part 4, the beat frequency of the laser light L1 and L2 is detected by the light detection part 4. Accordingly, the frequency difference between the laser light L1 and L2 is detected. With the frequency difference, the angular velocity of rotation can be obtained.

In this manner, for the semiconductor ring laser apparatus 1 according to the embodiment of the present invention, the first semiconductor layer 10n of the Si semiconductor substrate 10 is doped with B (boron) at high concentration to form the second semiconductor layer 13, and the semiconductor ring laser apparatus 1 is formed on an Si semiconductor substrate 10 by using a light emitting amplification function, an optical waveguide function, and a light detection function of the pn junction 13a obtained by performing an anneal treatment on the second semiconductor layer 13 while radiating light onto the second semiconductor layer 13. By so doing, the light emitting amplification part 2A and the light detection part 4 can be formed in a part of the optical waveguide 21. Therefore, by forming these in a sequence of photolithography steps, a complex optical axis alignment becomes unnecessary, stable oscillation of a ring laser becomes possible, and angular velocity detection with high precision becomes possible. Since the arithmetic processing part 5 that performs an arithmetic process of a detection signal of the light detection part 4 can be incorporated integrally in the Si semiconductor substrate 10, demand for achieving an extremely small size and extremely light weight can be met.

The embodiment of the present invention has been described above in detail with reference to the drawings. Specific configurations are not limited to those in the embodiment and are included in the present invention even with a change or the like in design without departing from the gist of the present invention. It is possible to apply and combine techniques of each embodiment described above, as long as a problem or contradiction is not particularly present in an object, configuration, and the like thereof.

### EXPLANATION OF REFERENCE NUMERALS

1: Semiconductor ring laser apparatus, 2: Semiconductor laser part,

2A: Light emitting amplification part,

3: Laser light extraction part, 4: Light detection part, 5: Arithmetic processing part,

10: Si semiconductor substrate, 10n: First semiconductor layer,

11: Insulation layer, 11a: Inner insulation layer, 11b, 11c Surface insulation layer,

12: N+ layer, 13: Second semiconductor layer, 13a: Pn junction,

14, 16: Metal electrode, 15: Transparent electrode,

20: Ring resonator, 21: Optical waveguide, 21A: Extraction optical waveguide,

22: Reflection part, L1, L2: Laser light

1. A semiconductor ring laser apparatus comprising:
an Si semiconductor substrate;
a ring resonator configured by an optical waveguide formed on said Si semiconductor substrate;
a semiconductor laser part that is provided with a light emitting amplification part at least in a part of said optical waveguide and that generates two beams of laser light traveling around in opposite directions in said ring resonator; and
a light detection part formed on said Si semiconductor substrate to extract said two beams of laser light from said ring resonator and detect a frequency difference between said two beams of laser light,
wherein said light emitting amplification part includes a pn junction obtained by performing an anneal treatment with light radiation to a second semiconductor layer which is obtained by doping a first semiconductor layer of said Si semiconductor substrate with B (boron) at high concentration.

2. The semiconductor ring laser apparatus according to claim 1, wherein said light detection part includes a pn junction obtained by performing an anneal treatment with light radiation to a second semiconductor layer which is obtained by doping a first semiconductor layer of said Si semiconductor substrate with B (boron) at high concentration.

3. The semiconductor ring laser apparatus according to claim 1, wherein said first semiconductor layer is an n-type semiconductor layer in which said Si semiconductor substrate is doped with arsenic (As).

4. The semiconductor ring laser apparatus according to claim 1,
wherein said Si semiconductor substrate is provided with an arithmetic processing part that performs an arithmetic process of a detection signal of said light detection part, and
wherein said arithmetic processing part is formed with an arithmetic processing circuit by a semiconductor device incorporated in said Si semiconductor substrate.

5. The semiconductor ring laser apparatus according to claim 1, wherein said ring resonator includes a plurality of linear optical waveguides of which a direction changes at a plurality of reflection parts formed on said Si semiconductor substrate.

6. The semiconductor ring laser apparatus according to claim 1, wherein said ring resonator includes an annular optical waveguide including a curved optical waveguide.

7. The semiconductor ring laser apparatus according to claim 2, wherein said first semiconductor layer is an n-type semiconductor layer in which said Si semiconductor substrate is doped with arsenic (As).

8. The semiconductor ring laser apparatus according to claim 2,
wherein said Si semiconductor substrate is provided with an arithmetic processing part that performs an arithmetic process of a detection signal of said light detection part, and
wherein said arithmetic processing part is formed with an arithmetic processing circuit by a semiconductor device incorporated in said Si semiconductor substrate.

9. The semiconductor ring laser apparatus according claim 3,
wherein said Si semiconductor substrate is provided with an arithmetic processing part that performs an arithmetic process of a detection signal of said light detection part, and
wherein said arithmetic processing part is formed with an arithmetic processing circuit by a semiconductor device incorporated in said Si semiconductor substrate.

10. The semiconductor ring laser apparatus according to claim 7,
wherein said Si semiconductor substrate is provided with an arithmetic processing part that performs an arithmetic process of a detection signal of said light detection part, and
wherein said arithmetic processing part is formed with an arithmetic processing circuit by a semiconductor device incorporated in said Si semiconductor substrate.

11. The semiconductor ring laser apparatus according to claim 2, wherein said ring resonator includes a plurality of linear optical waveguides of which a direction changes at a plurality of reflection parts formed on said Si semiconductor substrate.

12. The semiconductor ring laser apparatus according to claim 3, wherein said ring resonator includes a plurality of linear optical waveguides of which a direction changes at a plurality of reflection parts formed on said Si semiconductor substrate.

13. The semiconductor ring laser apparatus according to claim 7, wherein said ring resonator includes a plurality of linear optical waveguides of which a direction changes at a plurality of reflection parts formed on said Si semiconductor substrate.

14. The semiconductor ring laser apparatus according to claim 4, wherein said ring resonator includes a plurality of linear optical waveguides of which a direction changes at a plurality of reflection parts formed on said Si semiconductor substrate

15. The semiconductor ring laser apparatus according to claim 2, wherein said ring resonator includes an annular optical waveguide including a curved optical waveguide.

16. The semiconductor ring laser apparatus according to claim 3, wherein said ring resonator includes an annular optical waveguide including a curved optical waveguide.

17. The semiconductor ring laser apparatus according to claim 7, wherein said ring resonator includes an annular optical waveguide including a curved optical waveguide.

18. The semiconductor ring laser apparatus according to claim 4, wherein said ring resonator includes an annular optical waveguide including a curved optical waveguide.
